(19) United States
(12) Patent Application Publication
(10) Pub. No.: US 2024/0405049 A1
(43) Pub. Date: Dec. 5, 2024

(54) SENSOR PACKAGE AND A METHOD FOR FORMING THE SAME

(71) Applicant: STATS ChipPAC Pte. Ltd., Singapore (SG)

(72) Inventors: BumRyul MAENG, Incheon (KR); MyungHo JUNG, Gyeonggi-do (KR); HeeSoo LEE, Incheon (KR)

(21) Appl. No.: 18/673,384

(22) Filed: May 24, 2024

(30) Foreign Application Priority Data
May 29, 2023 (CN) 202310613818.X

(51) Int. Cl. H01L 27/146

(52) U.S. Cl. CPC H01L 27/14634; H01L 27/14618; H01L 27/14625; H01L 27/14636; H01L 27/1469

(57) ABSTRACT

A method for forming a sensor package is disclosed. The method comprises: providing a sensor; forming an optical filter and a transparent mold on the sensor to form a sensor assembly; providing a substrate, wherein one or more connectors are attached on a front surface of the substrate; forming a first encapsulant layer on the front surface of the substrate, wherein the one or more connectors are exposed from the first encapsulant layer; disposing the sensor assembly on the first encapsulant layer; connecting the sensor with the one or more connectors; and forming a second encapsulant layer on the first encapsulant layer to cover the sensor assembly.

### TECHNICAL FIELD

The present application generally relates to semiconductor packaging technology, and more particularly, to a sensor package and a method for forming a sensor package.

### BACKGROUND OF THE INVENTION

Recently, sensor development is accelerating due to the expansion of the automotive and wearable device markets. Previously, a sensor and a System-on-Chip (SoC) chip were manufactured individually. However, it is expected that the sensor and other desired electronic components including the SoC chip can be further integrated into a single package so that the overall package can be smaller but have more functions.

Therefore, a need exists for a sensor package that includes both a sensor and other desired electronic components.

### SUMMARY OF THE INVENTION

An objective of the present application is to provide a sensor package that includes both a sensor and other desired electronic components, and to provide a method for forming the sensor package.

According to one aspect of the present application, a method for forming a sensor package is provided. The method comprises: providing a sensor; forming an optical filter and a transparent mold on the sensor to form a sensor assembly; providing a substrate, wherein one or more connectors are attached on a front surface of the substrate; forming a first encapsulant layer on the front surface of the substrate, wherein the one or more connectors are exposed from the first encapsulant layer; disposing the sensor assembly on the first encapsulant layer; connecting the sensor with the one or more connectors; and forming a second encapsulant layer on the first encapsulant layer to cover the sensor assembly.

According to another aspect of the present application, a sensor package is provided. The sensor package comprises: a substrate; one or more electronic components formed on the substrate; one or more connectors formed on the substrate; a first encapsulant layer for encapsulating the one or more electronic components and the one or more connectors, wherein the one or more connectors are exposed from a front surface of the first encapsulant layer; a sensor formed on the first encapsulant layer and electrically coupled to the one or more connectors, wherein the sensor is formed on the first encapsulant layer; an optical filter formed on the sensor; a transparent mold formed on the optical filter; and a second encapsulant layer encapsulating the sensor, the optical filter and the transparent mold.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a sectional view showing a sensor package according to an embodiment of the present application.

FIG. 2 is a flow chart of a method for forming a sensor package according to an embodiment of the present application.

FIG. 3A to FIG. 3I are sectional views showing various steps of a method for forming a sensor package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

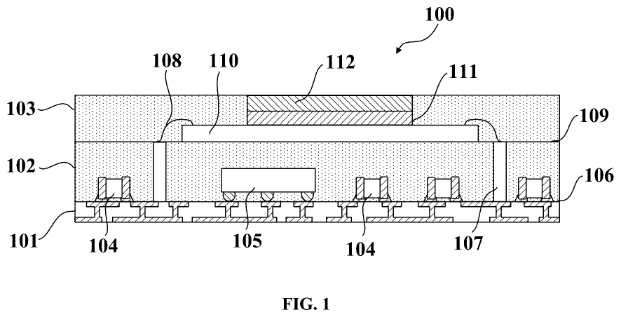

FIG. 1 illustrates a sensor package 100 according to an embodiment of the present application. The sensor package 100 integrates therewithin a sensor such as an optical sensor and other electronic components that may operate with the optical sensor, for example, to drive the optical sensor, or to receive and process electrical signals generated by the sensor. The sensor package 100 can operate as an image sensing system or image sensing assembly. In other words, the sensor package 100 is generally an all-in-one package that can implement image detection and processing functions, which can avoid or at least reduce other electronic components required in other similar image sensing systems.

As shown in FIG. 1, the sensor package 100 includes two layers of encapsulant which encapsulate a portion of the image sensing system, respectively. Preferably, an upper encapsulant layer of the two layers of encapsulant may be used to encapsulate the optical sensor which faces towards the environment and senses lights with its light receiving surface; and a lower encapsulant layer of the two layers of encapsulant may be used to encapsulate the other electronic components because they are not desired to be exposed to the environment for optical sensing purpose.

In particular, the sensor package 100 includes a substrate 101. In some embodiments, the substrate 101 may be a printed circuit board (PCB), a laminate interposer, a strip interposer, a leadframe, or another suitable substrate. The substrate 101 may include one or more insulating or passivation layers, one or more conductive vias formed through the insulating layers, and one or more conductive layers formed over or between the insulating layers. The substrate 101 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, or other reinforcement fibers or fabrics. The substrate 101 may also be a multi-layer flexible laminate, ceramic, copper clad laminate, glass, or semiconductor wafer including an active surface containing one or more transistors, diodes, and other circuit elements to implement analog circuits or digital circuits. The substrate 101 may include one or more electrically conductive layers or redistribution layers (RDL) formed using sputtering, electrolytic plating, electroless plating, or other suitable deposition process. The conductive layers may be one or more layers of Al, Cu, Sn, Ni, Au, Ag, Ti, W, or other suitable electrically conductive material. In some embodiments, one or more conductive patterns may be exposed from the surface of the substrate 101, and subsequently connected with solder balls or the like for subsequent mounting or connecting of other components or devices.

As can be seen, the sensor package 100 includes a first encapsulant layer 102 formed on the substrate 101 and a second encapsulant layer 103 formed on the first encapsulant layer 102. One or more electronic components, such as one or more passive devices 104 (e.g., capacitors or resistors) or one or more semiconductor dice 105, are formed on a front surface 106 of the substrate 101. These electronic components may be electrically coupled to certain conductive patterns (not shown) on the front surface 106 of the substrate 101 and therefore coupled to, for example, other conductive patterns on a back surface of the substrate 101 for further connection with an external system or device. Furthermore, the sensor package 100 may also include one or more connectors 107 mounted on the front surface 106 of the substrate 101. The connectors 107 provide connection between components mounted in the two encapsulant layers 102 and 103. In some embodiments, the connectors 107 may be metal bars. In some other embodiments, the connectors 107 may be vertical bonding wires.

The first encapsulant layer 102 can fully cover the one or more electronic components 104 and 105 to prevent them from damages, shocks and contaminants. Also, the first encapsulant layer 102 encapsulates the connectors 107 with only their top surfaces exposed, to provide protection as well as electrical connectivity. As shown, the connectors 107 may have a height greater than that of the various components such as the electronic components 104 and 105 encapsulated within the first encapsulant layer 102, so that the connectors 107 can be exposed from a front surface 109 of the first encapsulant layer 102.

On top of the first encapsulant layer 102, a sensor 110 is formed. The sensor 110 may be a lidar sensor, a light sensor, an image sensor, or any other suitable sensors. As can be seen, the sensor 110 may be electrically connected with the connectors 107 that are exposed from the first encapsulant layer 102 through bonding wires 108, for example. Therefore, the sensor 110 can be electrically connected with the other components (e.g., the electronic components 104 and 105) of the sensor package 100 to form an integrated package.

In some embodiments, an optical filter 111 may be formed on the sensor 110, for filtering lights transmitted from the environment to the sensor 110. In some embodiments, the optical filter 111 may take a shape similar to the shape of the sensor 110, and may fully cover the sensor 110 to uniformly filter out undesired light wavelengths that are emitted towards the sensor 110 from the external environment. Preferably, the optical filter 111 may include an optical filter film, which may selectively allow light of a certain wavelength range (smaller/larger than a wavelength, within a wavelength range, at a wavelength, etc.) to pass through. For example, the optical filter film may be thin-film optical filters of alternating thin layers of materials with special optical properties. The optical filter film may transmit, block or reflect light of different wavelength ranges. The optical filter film can be a bandpass filter, a notch filter, a shortpass edge filter, a longpass edge filter, a dichroic filter or a customized filter matching arbitrary ranges of wavelengths. Preferably, the optical filter film may be formed via a coating process. It can be appreciated that the optical filter film may be any optical filter film that is suitable for filtering lights for a sensor. It can also be appreciated that the optical filter 111 may include multiple filter layers having different optical properties, and a thickness of the optical filter 111 may vary according to the design and function of the overall sensor assembly.

The sensor package 100 also includes a transparent mold 112 formed on the optical filter 111. With the transparent mold 112, lights can be transmitted from the environment to the sensor 110, and also, the transparent mold 112 can provide protection for the optical filter 111 and the sensor 110, and can prevent water penetration into the sensor 110 together with the encapsulant material of the second encapsulant layer 103. The second encapsulant layer 103 can encapsulate the sensor 110, the optical filter 111 and the transparent mold 112, and prevent them from damages, shock or contaminants. In some embodiments, the transparent mold 112 may align vertically with the optical filter 111 due to the specific process for forming them, which will be elaborated below with more details. In some embodiments, the transparent mold 112 may include a clear epoxy molding material such as a clear epoxy resin. In some other embodiments, the transparent mold 112 may include other transparent encapsulant material such as infrared epoxy molding compound. The transparent mold 112 may optionally include a curing agent (hardener). The transparent mold 112 can be formed by coating, spraying, or inkjet depositing a liquid encapsulant material onto the optical filter 111. The transparent mold 112 can be non-conductive, provides structural support, and environmentally protect the sensor 110 and the optical filter 111 from external elements and contaminants.

In some embodiments, the two layers of electronic components of the sensor package 100 may be manufactured separately and then attached together. In that case, various different processes may be performed for the two layers of components. For example, the upper layer where the sensor 110 is encapsulated may be formed using a wafer level packaging process, i.e., filters, transparent molds and second encapsulant layer may be formed on respective sensors of a sensor wafer such as a silicon wafer before the sensor wafer is singulated into pieces or units, to improve production efficiency. Furthermore, once the sensor wafer is encapsulated and singulated into pieces or units, the sensor pieces or units may be mounted onto respective positions of a substrate, which may be implemented at a strip level, similar as conventional packaging processes. After that, the substrate may be further singulated into individual sensor packages.

FIG. 2 is a flow chart of a method 200 for forming a sensor package according to an embodiment of the present application, for example, for forming the sensor package 100 as shown in FIG. 1 or a similar sensor package.

The method 200 may start with step 201, and a sensor is provided. At step 202, an optical filter and a transparent mold are formed on the sensor to form a sensor assembly. At step 203, a substrate is provided, wherein one or more connectors are attached on a front surface of the substrate. Next, at step 204, a first encapsulant layer is formed on the front surface of the substrate, wherein the one or more connectors are exposed from the first encapsulant layer. At step 205, the sensor assembly is formed on the first encapsulant layer. At step 206, the sensor is connected with the one or more connectors. Afterwards, at Step 207, a second encapsulant layer is formed on the first encapsulant layer to cover the sensor assembly.

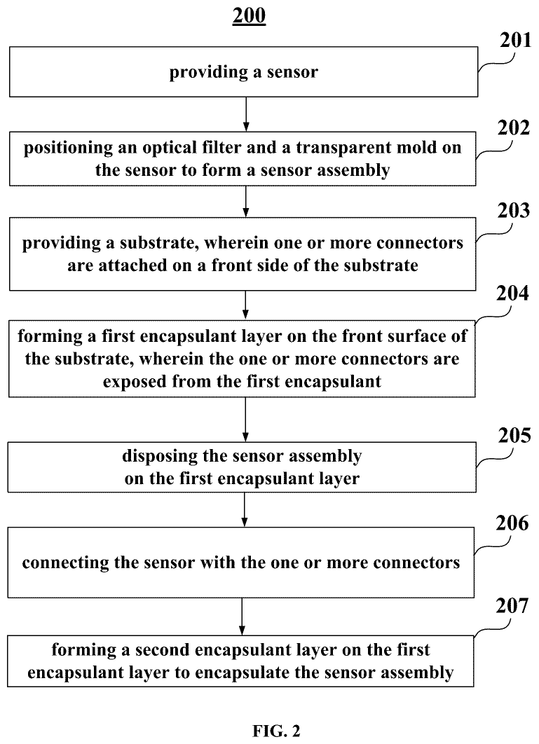

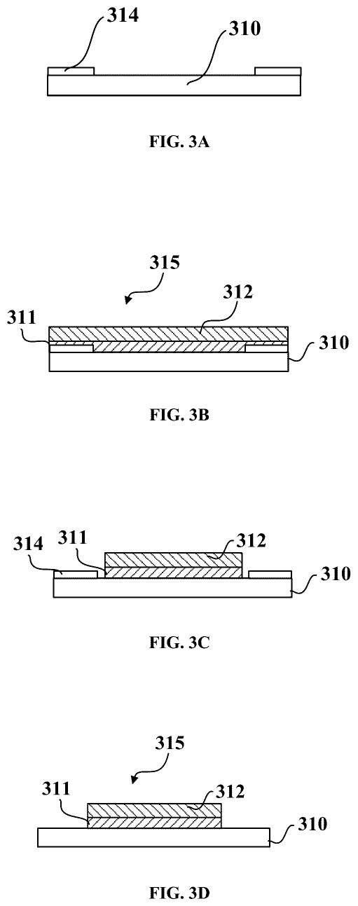

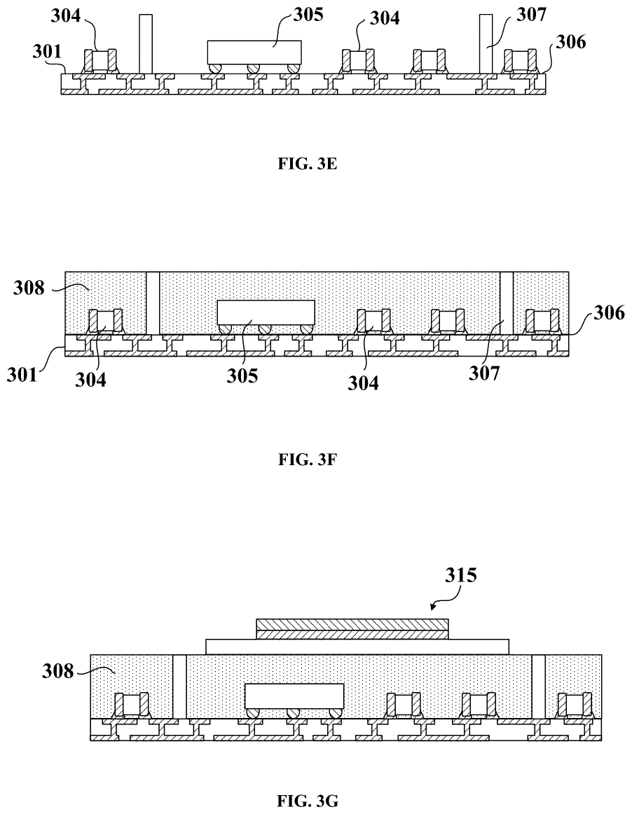

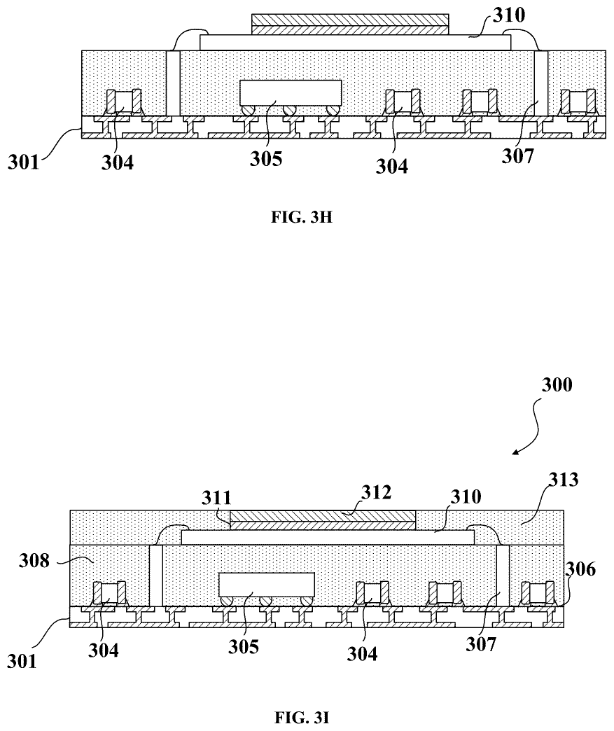

FIGS. 3A to 3I are sectional views showing various steps of a method for forming a sensor package according to an embodiment of the present application.

As shown in FIG. 3A, a sensor 310 is provided. It can be appreciated that the sensor 310 may not be individual sensor chips that have already been singulated from a sensor wafer. Rather, the sensor 310 may be an unsingulated sensor of a sensor wafer, with other identical or similar sensors in the sensor wafer as well. That is, a portion of the method for forming a sensor package may be implemented as a wafer level process. Although not shown in FIG. 3A, certain interconnect areas (not shown) may be formed on a front surface of the sensor 310 to provide for electrical connectivity of the sensor 310 with other electronic components of the sensor package.

A patterned photoresist layer 314 may be formed on the sensor 310, or particularly on the front surface of the sensor 310. The patterned photoresist layer 314 at least partially covers an interconnect area of the sensor 310 but exposes a sensor area of the sensor 310. In particular, a photoresist layer fully covering the front surface of the sensor 310 may be formed on top of the sensor front surface, for example, using printing, spin coating, or spray coating. Then the photoresist layer can be formed with certain patterns using such as a lithography process.

Next, as shown in FIG. 3B, an optical filter layer 311 and a transparent encapsulant layer 312 are formed on the sensor 310. In particular, the optical filter layer 311 is formed on top of the sensor front surface. The optical filter layer 311 covers and is in direct contact with the sensor area of the sensor 310 and the patterned photoresist layer. Preferably, the optical filter layer 311 fully covers the exposed portion of the sensor area and the patterned photoresist layer. Afterwards, the transparent encapsulant layer 312 is formed on top of the optical filter layer 311. Preferably, the transparent encapsulant layer 312 may entirely cover the entire optical filter layer 311.

Further referring to FIG. 3C, a portion of the transparent encapsulant layer 312 and a portion of the optical filter layer 311 are removed, so as to expose the patterned photoresist layer 314. In some embodiments, the removal may adopt a half-cut process performed with a saw or a laser cutting tool. The position where the half-cut process is performed is selected such that the patterned photoresist layer 314 is at least partially exposed after the half-cut process. A depth of the half-cut process may be equal to or larger than a total thickness of the transparent encapsulant layer 312 and the optical filter layer 311, yet smaller than the total thickness of the transparent encapsulant layer 312, the optical filter layer 311 and the patterned photoresist layer 314. In some embodiments where the depth of the half-cut process is smaller than the total thickness of the transparent encapsulant layer 312, the optical filter layer 311 and the patterned photoresist layer 314, some patterned photoresist layer 314 may remain on the sensor 310. In other words, the patterned photoresist layer 314 may not be fully removed so that the remaining photoresist layer 314 can protect the interconnect area thereunder from damage during the half-cut process. The remaining patterned photoresist layer 314 may be removed later with a photoresist stripping process such as organic stripping, inorganic stripping or dry stripping, as shown in FIG. 3D. As such, a sensor assembly 315 is formed. After the half cut process, the optical filter layer 311 and transparent encapsulant layer 312 can be patterned as an optical filter 311 and a transparent mold 312, respectively.

It can be appreciated that if the sensor is manufactured with other similar sensors on the same wafer, a singulation process may be performed to separate these sensors from each other, which will not be elaborated herein.

On the other hand, other electronic components can be encapsulated separately on a substrate 301, as shown in FIG. 3E, which will be integrated with the sensor assembly in a later process. In particular, one or more electronic components such as one or more passive devices 304 (e.g., capacitors or resistors) and one or more semiconductor dice 305 may be attached on a front surface 306 of the substrate 301, and one or more connectors 307 may also be attached on the front surface 306 of the substrate 301. In some embodiments, the connectors 307 may be metal bars. In some other embodiments, the connectors 307 may be vertical bonding wires. It can be appreciated that another number of electronic components may be mounted on the substrate 301, either on the same surface or on both surfaces of the substrate 301.

Next, as shown in FIG. 3F, a first encapsulant layer 308 is formed on the front surface 306 of the substrate 301. The first encapsulant layer 308 may be formed of an encapsulant material. In some embodiments, the first encapsulant layer 308 may be formed using a compression molding process or an injection molding process. In some other embodiments, the first encapsulant layer 308 may be formed using paste printing, transfer molding, liquid encapsulant molding, vacuum lamination, spin coating, or other suitable process. The first encapsulant layer 308 may be made of polymer composite material, such as epoxy resin with filler, epoxy acrylate with filler, or polymer with proper filler, but the scope of this application is not limited thereto. As shown in FIG. 3F, the connectors 307 can be exposed from the first encapsulant layer 308, for connecting the sensor 310 of the sensor package to the substrate 301, which will be discussed in detail below.

In some embodiments, the first encapsulant layer 308 may be first formed on the first surface 306 of the substrate 301, with excess encapsulant materials. Then, a portion of the first encapsulant layer 308 may be grinded to expose the connectors 307, as shown in FIG. 3F.

Next, as shown in FIG. 3G, the sensor assembly 315 as formed can be formed on the first encapsulant layer 308, for example, via an adhesive material. As shown in FIG. 3H, the sensor 310 is electrically coupled to the connectors 307 via bonding wires, so that the sensor 310 can be electrically coupled to the substrate 301 as well as other electronic components such as the passive devices 304 and the semiconductor dice 305.

Further, as shown in FIG. 3I, a second encapsulant layer 313 is formed on the first encapsulant layer 308, to cover the sensor 310, the optical filter 311 and the transparent mold 312. The second encapsulant layer 313 may not cover a top surface of the transparent mold 312 such that it may not affect light transmission through the transparent mold 312. The material and the process for forming the second encapsulant layer 313 may be similar as those for forming the first encapsulant layer 308.

In some embodiments, the steps as shown in FIGS. 3E to 3I may be implemented on a strip type substrate 301, and accordingly, a singulation process may be performed to separate the substrate 301 into pieces, with each piece having a set of electronic components and an optical sensor, etc.

Therefore, a sensor package 300 which has a higher density that includes both a sensor and other desired electronic components is formed.

The sensor package disclosed in the invention includes a vertical wire bonding structure, i.e., the sensor and other desired electronic components are vertically stacked and bonded together, therefore the sensor and other desired electronic components that play different roles can be integrated into one package. Thus, the thickness of the package can be decreased compared with the whole thickness of the previous sensor and the SoC (System-on-Chip) that were manufactured individually.

In addition, by encapsulating the sensor with an encapsulant and stacking an optical filter and a transparent mold onto the sensor, water penetration can be prevented, and the reliability of the sensor may be better than a previous sensor with commonly used lid or metal cap. Also, the commonly used lid or metal cap may have a problem of delamination phenomenon, while the sensor package in the invention does not include a lid or metal cap, so the delamination phenomenon can be avoided.

The discussion herein included numerous illustrative figures that showed various portions of a sensor package and a method for forming a sensor package. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a sensor package, comprising:
providing a sensor;
forming an optical filter and a transparent mold on the sensor to form a sensor assembly;
providing a substrate, wherein one or more connectors are attached on a front surface of the substrate;
forming a first encapsulant layer on the front surface of the substrate, wherein the one or more connectors are exposed from the first encapsulant layer;
disposing the sensor assembly on the first encapsulant layer;
connecting the sensor with the one or more connectors; and
forming a second encapsulant layer on the first encapsulant layer to cover the sensor assembly.

2. The method for claim 1, wherein providing a sensor comprises forming a patterned photoresist layer on the sensor.

3. The method for claim 2, wherein forming an optical filter and a transparent mold on the sensor comprises:
forming an optical filter layer on the sensor;
forming a transparent encapsulant layer on the optical filter layer; and
removing a portion of the optical filter layer and a portion of the transparent encapsulant layer to form the optical filter and the transparent mold, so as to expose the patterned photoresist layer on the sensor.

4. The method for claim 3, wherein forming an optical filter and a transparent mold on the sensor comprises further comprises:
after removing a portion of the optical filter layer and a portion of the transparent encapsulant layer, removing the patterned photoresist layer from the sensor.

5. The method of claim 1, wherein before forming a first encapsulant layer on the front surface of the substrate, the method further comprises:
attaching one or more electronic components on the front surface of the substrate.

6. The method of claim 5, wherein the one or more electronic components are electrically coupled to the one or more connectors.

7. The method for claim 1, wherein forming a first encapsulant layer on the front surface of the substrate further comprises:
grinding a portion of the first encapsulant layer to expose the one or more connectors.

8. The method for claim 1, wherein the one or more connectors comprise one or more metal bars.

9. The method for claim 1, wherein the one or more connectors comprise one or more vertical bonding wires.

10. A sensor package, comprising:
a substrate;
one or more electronic components formed on the substrate;
one or more connectors formed on the substrate;
a first encapsulant layer for encapsulating the one or more electronic components and the one or more connectors, wherein the one or more connectors are exposed from a front surface of the first encapsulant layer;
a sensor formed on the first encapsulant layer and electrically coupled to the one or more connectors, wherein the sensor is formed on the first encapsulant layer;
an optical filter formed on the sensor;
a transparent mold formed on the optical filter; and
a second encapsulant layer encapsulating the sensor, the optical filter and the transparent mold.

11. The sensor package of claim 10, wherein the one or more connectors comprise one or more metal bars.

12. The sensor package of claim 10, wherein the one or more connectors comprise one or more vertical bonding wires.

13. The sensor package of claim 10, wherein the sensor comprises an optical sensor.
